(19) United States
(12) Patent Application Publication
(10) Pub. No.: US 2006/0049856 A1
(43) Pub. Date: Mar. 9, 2006

(54) Load-driving semiconductor device that detects current flowing through load by resistor

(76) Inventors: Tatsuji Nakai, Kyoto-shi (JP); Makoto Kuwamura, Kyoto-shi (JP)

Correspondence Address: FISH & RICHARDSON P.C., P.O. BOX 1022, MINNEAPOLIS, MN, 55440-1022, US

(21) Appl. No.: 11/212,993

(22) Filed: Aug. 26, 2005

(30) Foreign Application Priority Data
Sep. 3, 2004 (JP) 2004-257705

(51) Int. Cl. H03K 5/153

(52) U.S. Cl. 327/83

(57) ABSTRACT

In a load-driving semiconductor device, a part of metal interconnection in a metal interconnection layer is used to form a detecting resistor for detecting an output current, and a resistance-measuring pad for measuring a resistance value of the detecting resistor is provided. The load-driving semiconductor device generates a trimmed reference voltage in accordance with the resistance value of the detecting resistor, and controls drive of a load based on a comparison between the reference voltage and a detected voltage according to a voltage drop of the detecting resistor. Therefore, it is possible to provide a load-driving semiconductor device in which a current-detecting resistor for detecting a current that flows through a load is embedded to reduce space required on a substrate and thus reduce cost, and a current can be detected with high accuracy.

### BACKGROUND OF THE INVENTION

1. Field of the Invention

The present invention relates to a load-driving semiconductor device that detects a current flowing through a load such as a motor to drive the load.

2. Description of the Background Art

In a load-driving device for driving a load such as a motor, a load current flowing through the load has conventionally been detected to control or limit the current or control a torque by using a semiconductor device (IC) for driving a load. To detect the load current, a discrete (external) current-detecting resistor is provided to utilize its voltage drop to detect the amount of load current (Japanese Patent Laying-Open No. 2003-209993).

The resistance value of the detecting resistor is usually set to be considerably low (e.g. approximately 0.1-0.5 Ω) to apply a sufficient voltage to the load and reduce a loss caused by the detecting resistor itself. The size of the current-detecting resistor is quite large, which requires large space for mounting the same on a substrate and also contributes to cost increase.

The voltage drop of the detecting resistor is compared with a reference voltage in the IC. However, a temperature difference between the detecting resistor and the load-driving IC disadvantageously causes a mismatch of the characteristics between the voltage drop and the reference voltage.

### SUMMARY OF THE INVENTION

An object of the present invention is to provide a load-driving semiconductor device in which a current-detecting resistor for detecting a current flowing through a load is embedded to reduce space required on a substrate, reduce cost, and enable the current to be detected with high accuracy.

To summarize, the present invention is a load-driving semiconductor device for controlling drive of a load. A load-driving semiconductor device 100 includes a detecting resistor 30 formed of metal interconnection and for detecting an output current Io to the load M, and at least one resistance-measuring pad PAD1 and PAD2 for measuring a resistance value of the detecting resistor.

Preferably, load-driving semiconductor device 100 further includes a reference-voltage generator circuit 40 and 50 for generating an adjustable reference voltage Vref, and a control circuit 20 and 60 for controlling the drive of load M based on reference voltage Vref and a detected voltage Vdet according to a voltage drop of detecting resistor 30.

More preferably, load-driving semiconductor device 100 has a multi-layered metal interconnection layer, and detecting resistor 30 is formed by using metal interconnection of an uppermost layer in the multi-layered metal interconnection layer.

More preferably, load-driving semiconductor device 100 further includes a voltage-measuring pad PAD3 for measuring reference voltage Vref.

More preferably, the reference-voltage generator circuit includes a voltage generator circuit 40 for generating a prescribed value of a generated voltage Vgen, and a trimming circuit 50 for trimming generated voltage Vgen to generate reference voltage Vref.

More preferably, trimming circuit 50 has a resistor-based voltage divider circuit having a plurality of resistors for dividing the generated voltage to output the reference voltage, and a connecting portion connected in parallel to any of the plurality of resistors and disconnectably configured to adjust reference voltage Vref.

More preferably, load-driving semiconductor device 100 further includes a voltage-measuring pad PAD3 for measuring reference voltage Vref.

More preferably, voltage generator circuit 40 is configured to generate generated voltage Vgen having a temperature coefficient of voltage substantially similar to a temperature coefficient of resistance of detecting resistor 30.

More preferably, load-driving semiconductor device 100 further includes a voltage-measuring pad PAD3 for measuring reference voltage Vref.

More preferably, trimming circuit 50 has a resistor-based voltage divider circuit having a plurality of resistors for dividing generated voltage Vgen to output reference voltage Vref, a switch connected in parallel to any of the plurality of resistors, and a switch control circuit 56 for controlling the switch to one of a conductive state and a non-conductive state to adjust reference voltage Vref.

More preferably, load-driving semiconductor device 100 further includes a voltage-measuring pad PAD3 for measuring reference voltage Vref.

More preferably, voltage generator circuit 40 is configured to generate generated voltage Vgen having a temperature coefficient of voltage substantially similar to a temperature coefficient of resistance of detecting resistor 30.

More preferably, load-driving semiconductor device 100 further includes a voltage-measuring pad PAD3 for measuring reference voltage Vref.

More preferably, voltage generator circuit 40 is configured to generate generated voltage Vgen having a temperature coefficient of voltage substantially similar to a temperature coefficient of resistance of detecting resistor 30.

More preferably, load-driving semiconductor device 100 further includes a voltage-measuring pad PAD3 for measuring reference voltage Vref.

More preferably, load-driving semiconductor device 100 further includes a voltage-measuring pad PAD3 for measuring reference voltage Vref.

More preferably, load-driving semiconductor device 100 further includes a voltage-measuring pad PAD3 for measuring reference voltage Vref.

Preferably, load-driving semiconductor device 100 has a multi-layered metal interconnection layer, and detecting resistor 30 is formed of metal interconnection of an uppermost layer in the multi-layered metal interconnection layer.

The present invention is, according to another aspect, a load-driving semiconductor device for controlling drive of a load. A load-driving semiconductor device 100 (200) includes a detecting resistor 30 (230) formed of metal interconnection and for detecting an output current Io to the load M, at least one resistance-measuring pad PAD1 and PAD2 for measuring a resistance value of detecting resistor 30 (230), a reference-voltage generator circuit 40 and 50 (250) for generating an adjustable reference voltage Vref, and a control circuit 20 and 60 (225, 260) for controlling the drive of load M based on a comparative signal obtained by comparing reference voltage Vref with a detected voltage Vdet according to a voltage drop of the detecting resistor. The control circuit controls timing of a control signal to an output transistor circuit in accordance with a prescribed control logic, and controls a level of the control signal based on the comparative signal.

Preferably, the control circuit 225 and 260 further controls a level of the comparative signal in accordance with a comparative output obtained by comparing an output voltage applied to the load and a voltage Vsb set to prevent saturation and adjustable in accordance with detected voltage Vdet.

Therefore, a major advantage of the present invention is that since a part of the metal interconnection layer in the semiconductor device is used to form a current-detecting resistor, space required to serve as a load-driving device can be reduced and the cost thereof can be kept low when compared to the conventional load-driving device using an external resistor. Another advantage of the present invention is that in the case of a multi-layered (e.g. three-layer) metal interconnection layer, an uppermost layer in the metal interconnection layer, which is usually formed to have a larger thickness than lower layers, is used as a current-detecting resistor, and thus a required area can be reduced.

Generally, it is difficult to form the metal interconnection to have a resistance value exactly matched to a predetermined resistance value. In the present invention, a measuring pad for measuring a resistance value of the detecting resistor is provided, and in accordance with the measured resistance value, a value of the reference voltage is trimmed (adjusted). A still another advantage of the present invention is that the difficult problem associated, for example, with an accurate setting of the resistance value in forming the metal interconnection is solved and the reference value and the detected value can properly be compared.

Moreover, in the present invention, both of the current-detecting resistor and the reference-voltage generator circuit are formed on the same semiconductor device, and hence undergo approximately the same temperature change. In addition, the reference-voltage generator circuit has a temperature coefficient of voltage substantially similar to the temperature coefficient of resistance of the metal interconnection. A further advantage of the present invention is that a mismatch of the characteristics between the reference value and the detected value conventionally caused by a difference in heat generation between an external resistor and an IC can almost be eliminated.

A further advantage of the present invention is that the present invention can widely and suitably be applied to an electrical device for detecting an output current to a load or a load current.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a structure of a load-driving semiconductor device according to a first embodiment of the present invention.

FIG. 2 shows a structure of a load-driving semiconductor device according to a second embodiment of the present invention.

FIG. 3 shows a structure of a load-driving semiconductor device according to a third embodiment of the present invention.

FIG. 4 shows an example of a structure of a predriver in FIG. 3.

FIG. 5 shows a structure of a load-driving semiconductor device according to a fourth embodiment of the present invention.

FIG. 6 shows an example of a structure of a circuit for generating a voltage set to prevent saturation shown in FIG. 5.

### DESCRIPTION OF THE PREFERRED EMBODIMENTS

The embodiments of the load-driving semiconductor device (integrated circuit: IC) according to the present invention will now be described in reference to the drawings. In the embodiments below, an example in which a motor is used as a load is described. However, the description can also be applied to any other loads in a similar manner, not being limited to a motor.

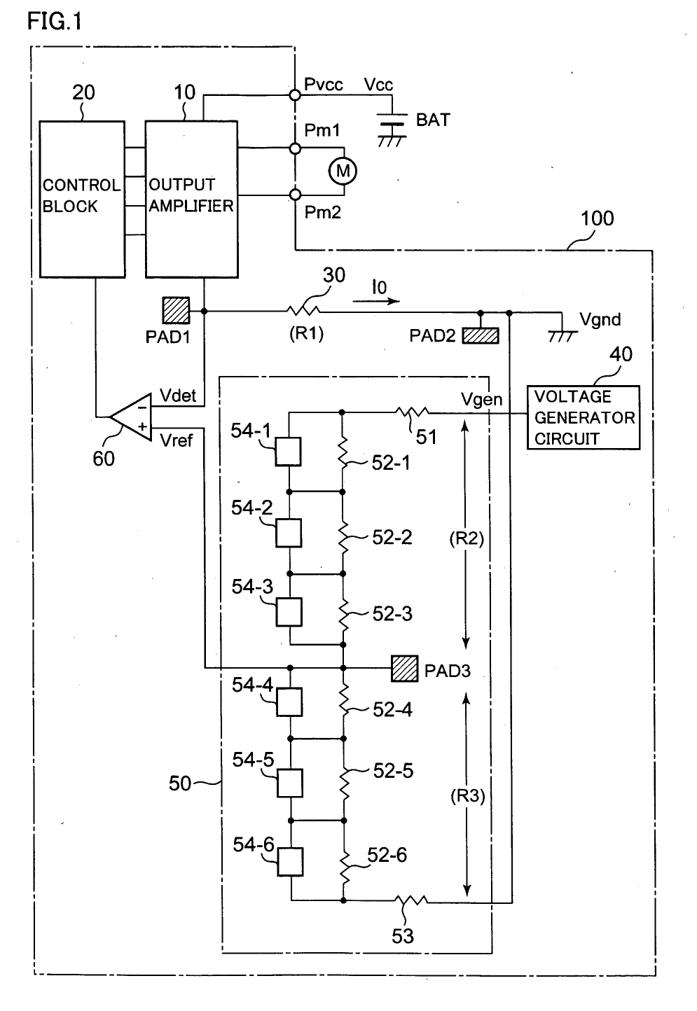

FIG. 1 shows a structure of a load-driving semiconductor device according to a first embodiment of the present invention.

In FIG. 1, a supply voltage Vcc is input from a battery power supply BAT to a load-driving semiconductor device 100 via a power supply input terminal Pvcc. From load-driving semiconductor device 100, an output voltage and an output current are supplied to a motor M, which serves as a load, via output terminals Pm1 and Pm2.

An output amplifier 10 includes, for example, an output transistor circuit using a transistor. The output transistor circuit is controlled in accordance with a control signal coming from a control block 20. Via the transistor circuit controlled in accordance with the control signal, the output current is supplied from output amplifier 10 to motor M. The output current Io passes through a detecting resistor 30 to flow into a ground voltage Vgnd. Since a resistance value of detecting resistor 30 is represented as R1, a detected voltage Vdet is represented by Io×R1.

Detecting resistor 30 is formed by using a part of metal interconnection of a metal interconnection layer in load-driving semiconductor device 100. For the metal interconnection layer, aluminum or an aluminum alloy (hereinafter collectively referred to as aluminum) is suitably used.

The metal interconnection layer is often muli-layered (e.g. made of three layers). In this case, the uppermost layer in the metal interconnection layer is usually formed to have a larger thickness than the remaining layers. If the multi-layered metal interconnection layer is formed in the present invention, a part of metal interconnection in the uppermost layer of the metal interconnection layer is used to form detecting resistor 30. Accordingly, an area of interconnection required to flow output current Io can be reduced.

In the following description, the uppermost layer (i.e. the outermost layer) of a three-layer aluminum interconnection layer is used as detecting resistor 30.

If detecting resistor 30 is formed of an aluminum interconnection layer, its resistance value is as low as approximately 0.1-0.5 Ω. Therefore, it is difficult to exactly obtain a prescribed resistance value (e.g. 0.2 Ω).

Therefore, in the present invention, resistance value R1 of detecting resistor 30 formed in the aluminum interconnection layer is measured in a wafer state, and a reference voltage Vref is made to be equal to a required value (R1×Io) based on measured resistance value R1 and a prescribed level of output current Io by trimming.

For this purpose, resistance measuring pads PAD1 and PAD 2 are provided at opposite ends of a portion of the aluminum interconnection which is to be detecting resistor 30. Resistance value R1 between pads PAD1 and PAD2 is measured in a wafer state. Since these pads are not terminals connected to the outside, the number of terminals does not increase, which causes almost no increase in size and cost of the semiconductor device.

Reference voltage Vref is then variably adjusted in accordance with measured resistance value R1 of detecting resistor 30 and output by a reference-voltage generator circuit composed of a voltage generator circuit 40 and a trimming circuit 50.

Voltage generator circuit 40 generates a prescribed value of a generated voltage Vgen. Generated voltage Vgen preferably has a temperature coefficient of voltage substantially similar to a temperature coefficient of resistance of the aluminum interconnection layer, which is to be detecting resistor 30.

In other words, since resistance value R1 of detecting resistor 30 varies in accordance with a temperature coefficient of resistance of the aluminum interconnection layer, it is preferable that reference voltage Vref to be compared, and a base of reference voltage Vref, namely, generated voltage Vgen also vary in accordance with resistance value R1 of detecting resistor 30 that varies according to a temperature. To vary reference voltage Vref and generated voltage Vgen as such, voltage generator circuit 40 is designed to use a circuit having a prescribed temperature coefficient of voltage (which is equivalent to a temperature coefficient of resistance of the aluminum interconnection layer) instead of a circuit whose temperature coefficient of voltage is zero.

Trimming circuit 50 forms a resistor-based voltage divider circuit in which a resistor 51, resistors 52-1 to 52-6, and resistor 53 are connected in series. One end of the resistor-based voltage divider circuit is connected to voltage generator circuit 40 and generated voltage Vgen is applied thereto, while the other end is connected to pad PAD2 or its periphery. If a stable ground voltage Vgnd point can be obtained, the other end of the resistor-based voltage divider circuit may be connected to ground voltage Vgnd point, and pad PAD2 may not be used. In the structure of the trimming circuit, the number of resistors and how these resistors are connected are only illustrative, and may be changed as needed.

Fuses 54-1 to 54-6, which are disconnectably configured connecting portions, are provided in parallel with resistors 52-1 to 52-6 of the resistor-based voltage divider circuit, respectively. Fuses 54-1 to 54-6 can be broken by, for example, laser. Reference voltage Vref is output from a connecting point of resistors 52-3 and 52-4.

When a combined resistance value obtained from resistor 51 and resistors 52-1 to 52-3 is represented as R2, and a combined resistance value obtained from resistors 52-4 to 52-6 and resistor 31 is represented as R3, reference voltage Vref is represented by an equation “Vref=Vgen×{R3/(R2+R3)}”. Fuses 54-1 to 54-6 are selectively broken such that reference voltage Vref is made to be equal to required value (R1×Io), which is based on a product of resistance value R1 of detecting resistor 30 and a prescribed level of output current Io. Furthermore, a voltage-measuring pad PAD3 for measuring a level of reference voltage Vref may be provided at the connecting point of resistors 52-3 and 52-4. By measuring adjusted reference voltage Vref with the use of voltage-measuring pad PAD3, a result of trimming can be checked.

As such, trimming circuit 50 includes the resistor-based voltage divider circuit having the plurality of resistors 51, 52-1 to 52-6, and 53 for dividing generated voltage Vgen and adjusting and outputting reference voltage Vref, and fuses 54-1 to 54-6 connected in parallel with prescribed resistors 52-1 to 52-6 of the resistor-based voltage divider circuit. When fuses 54-1 to 54-6 are selectively broken by laser in accordance with the resistance value of detecting resistor 30, trimming circuit 50 generates reference voltage Vref trimmed (adjusted) to a prescribed value.

Reference voltage Vref variably adjusted in accordance with the resistance value of detecting resistor 30, and detected voltage Vdet according to a voltage drop of detecting resistor 30 are input to an error amplifier 60. Error amplifier 60 supplies an error signal based on a difference between two input voltages, namely, reference voltage Vref and detected voltage Vdet to a control block 20. A control circuit including control block 20 and error amplifier 60 controls drive of a load M.

As such, in the present invention, a part of the metal interconnection layer (mainly an aluminum interconnection layer) in the semiconductor device is used to form current-detecting resistor 30. Therefore, when compared to the conventional semiconductor device using an external resistor, space required to serve as a load-driving device can be reduced and cost can be kept low. In addition, since the uppermost layer of the metal interconnection layer, which is usually made to have a larger thickness than the lower layers, is used for current-detecting resistor 30, a required area can be reduced.

Moreover, measuring pads PAD1 and PAD2 for measuring a resistance value of detecting resistor 30 are provided, and reference voltage Vref are trimmed (adjusted) in accordance with the measured resistance value. Therefore, it is possible to solve a difficult problem associated with an accurate setting of the resistance value of the aluminum interconnection, and properly compare reference voltage Vref and detected voltage Vdet.

Furthermore, since detecting resistor 30, voltage generator circuit 40, and trimming circuit 50 are formed in the same semiconductor device, all of them vary in accordance with the temperature in a substantially similar manner. Additionally, by allowing voltage generator circuit 50 to have a temperature coefficient of voltage substantially similar to a temperature coefficient of resistance of the aluminum interconnection, it is possible to virtually eliminate the mismatch of the characteristics between reference voltage Vref and detected voltage Vdet, which has conventionally been caused by, for example, heat generated by an external resistor.

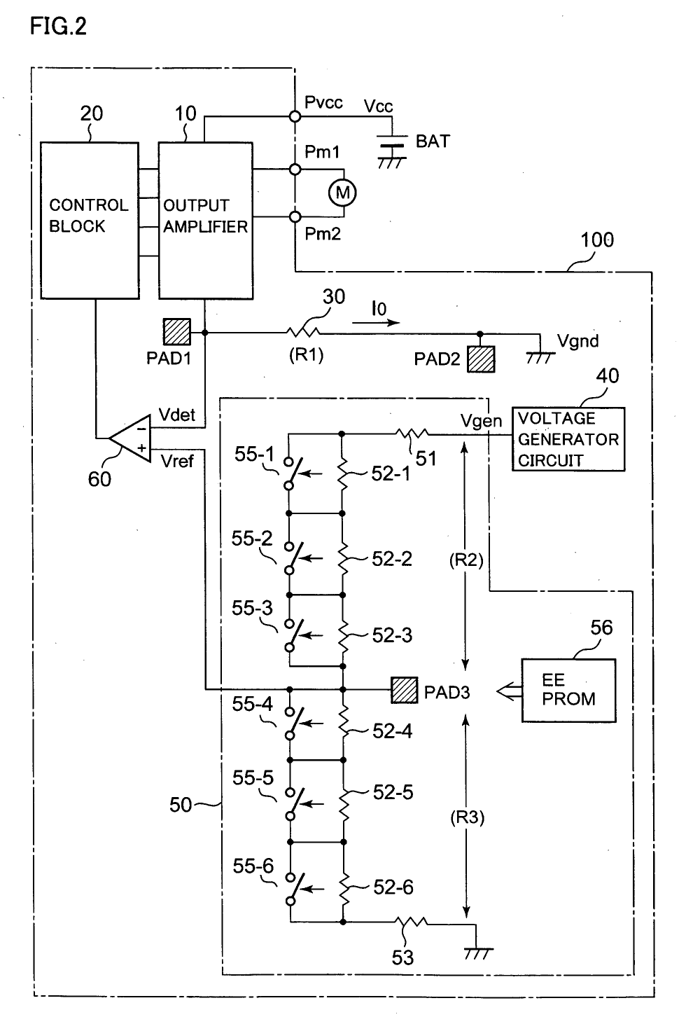

FIG. 2 shows a structure of a load-driving semiconductor device according to a second embodiment of the present invention. In FIG. 2, switches 55-1 to 55-6 are used instead of the disconnectably configured connecting portions of trimming circuit 50 in FIG. 1, namely, fuses 54-1 to 54-6. A non-volatile storage 56 is provided to serve as a switch control circuit for storing information for setting switches 55-1 to 55-6 to an on or off state and controlling them. For switches 55-1 to 55-6, a MOS transistor, a bipolar transistor and the like can be used. For nonvolatile storage 56, an Electrically Erasable and Programmable Read Only Memory (EEPROM), a Ferroelectric Random Access Memory (FeRAM) and the like can be used.

Nonvolatile storage 56 stores information for controlling switches 55-1 to 55-6 to an on or off state for trimming in accordance with the measured resistance value of detecting resistor 30 as in the process of trimming reference voltage Vref in FIG. 1. Each of switches 55-1 to 55-6 is switched to an on or off state based on the information for controlling the switches stored in nonvolatile storage 56. The other features are similar to those in the operation of load-driving semiconductor device 100 in FIG. 1.

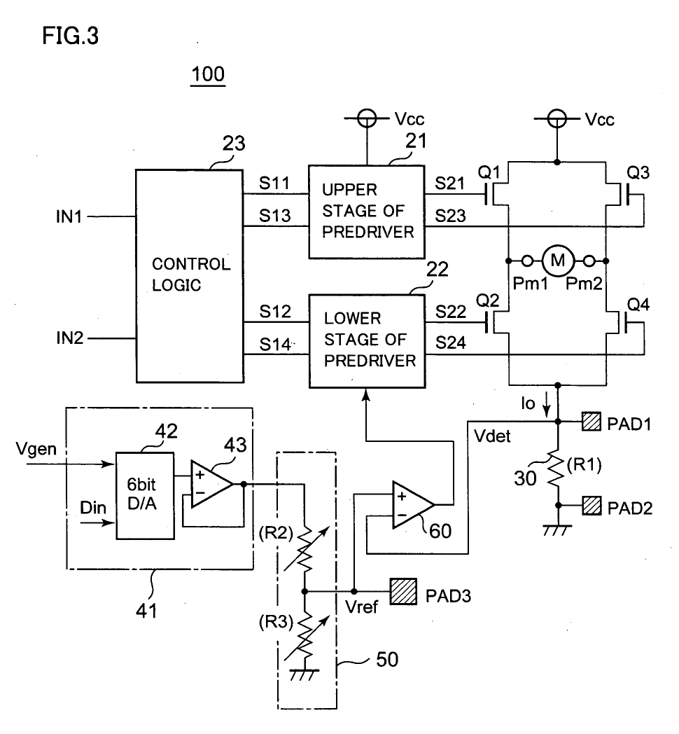

FIG. 3 shows a structure of a load-driving semiconductor device according to a third embodiment of the present invention, providing a more specific structure of control block 20 and output amplifier 10 in FIGS. 1 and 2.

In FIG. 3, trimming circuit 50 is shown to have two components, namely, adjustable resistors (their resistance values are represented as R2 and R3).

Generated voltage Vgen from voltage generator circuit 40 is converted by a voltage converter circuit 41 and supplied to trimming circuit 50. In this example, voltage converter circuit 41 is composed of a 6-bit D/A converter 42 and a voltage follower 43. Generated voltage Vgen is converted to a prescribed voltage in accordance with a digital command signal Din input to D/A converter 42, and then output from voltage converter circuit 41.

By providing voltage converter circuit 41, a voltage can be adjusted (trimmed) not only in trimming circuit 50 but by digital command signal Din. Therefore, reference voltage Vref can be trimmed within wider range and reference voltage Vref can optionally be varied in accordance with the operating conditions of motor M.

Alternatively, trimming circuit 50 may not be used, and voltage converter circuit 41 may trim reference voltage Vref In this case, voltage converter circuit 41 functions as a trimming circuit. Voltage converter circuit 41 may also be adopted in load-driving semiconductor device 100 shown in FIGS. 1 and 2 in a similar manner.

FIG. 3 shows a structure of load-driving semiconductor device 100 for driving motor M by an output amplifier of H-bridge type. Metal Oxide Semiconductor (MOS) transistors are used for output transistors Q1-Q4 embedded in the output amplifier.

In FIG. 3, when control inputs IN1 and IN2 are input to a control logic circuit 23 included in control block 20, logic signals S11-S14 are supplied to an upper circuit 21 and a lower circuit 22 of a predriver in accordance with logics of control inputs IN1 and IN2. Control signals S21-S24 are supplied to gates of output transistors Q1-Q4 from upper circuit 21 and lower circuit 22 to control on/off and conductivity of output transistors Q1-Q4. Upper circuit 21 and lower circuit 22 are included in control block 20.

If output transistors Q1 and Q4 are turned on at an H level of control input IN1 and at an L level of control input IN2, output current Io flows through a path from a power supply node Vcc through output transistor Q1, motor M, output transistor Q4, and detecting resistor 30 to ground voltage Vgnd point. Detected voltage Vdet according to output current Io and resistance value R1 is generated at detecting resistor 30.

Lower circuit 22 of the predriver is controlled by an output of error amplifier 60 such that detected voltage Vdet is equal to reference voltage Vref. Lower circuit 22 controls a control signal (gate voltage) S24 to be supplied to output transistor Q4 in accordance with the output of error amplifier 60. Accordingly, the current can be limited such that the current does not exceed a prescribed output current value.

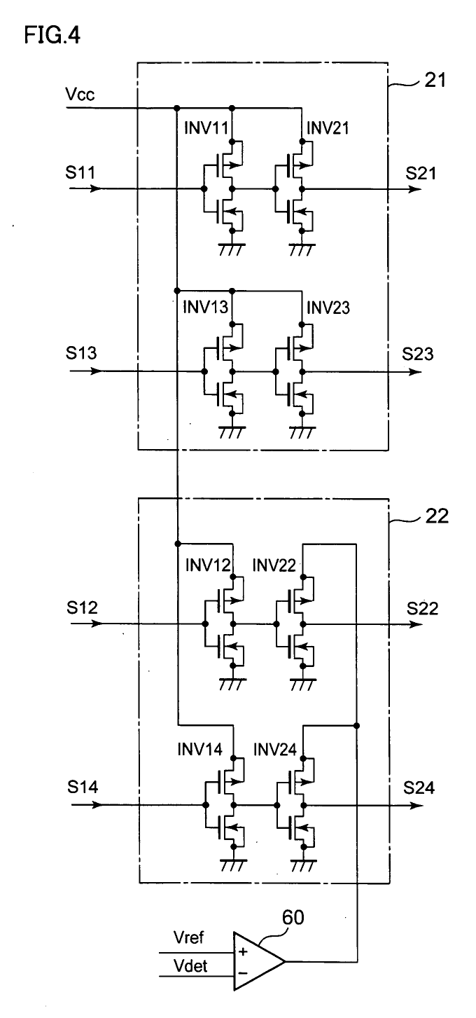

FIG. 4 shows an example of internal structures of upper circuit 21 and lower circuit 22. Upper circuit 21 amplifies logic signals S11 and S13 and outputs these signals as control signals S21 and S23 by Complementary MOS (CMOS) inverters INV11, INV21 and INV 13, INV 23 using supply voltage Vcc as an operating power supply. In contrast, lower circuit 22 outputs control signal S22, which is an amplified and amplitude-limited logic signal S12, by a CMOS inverter INV12 using supply voltage Vcc as an operating power supply and a CMOS inverter INV 22 using the output of error amplifier 60 as an operating power supply. Lower circuit 22 also outputs control signal S24, which is an amplified and amplitude-limited logic signal S14, by a CMOS inverter INV14 using supply voltage Vcc as an operating power supply and a CMOS inverter INV 24 using the output of error amplifier 60 as an operating power supply.

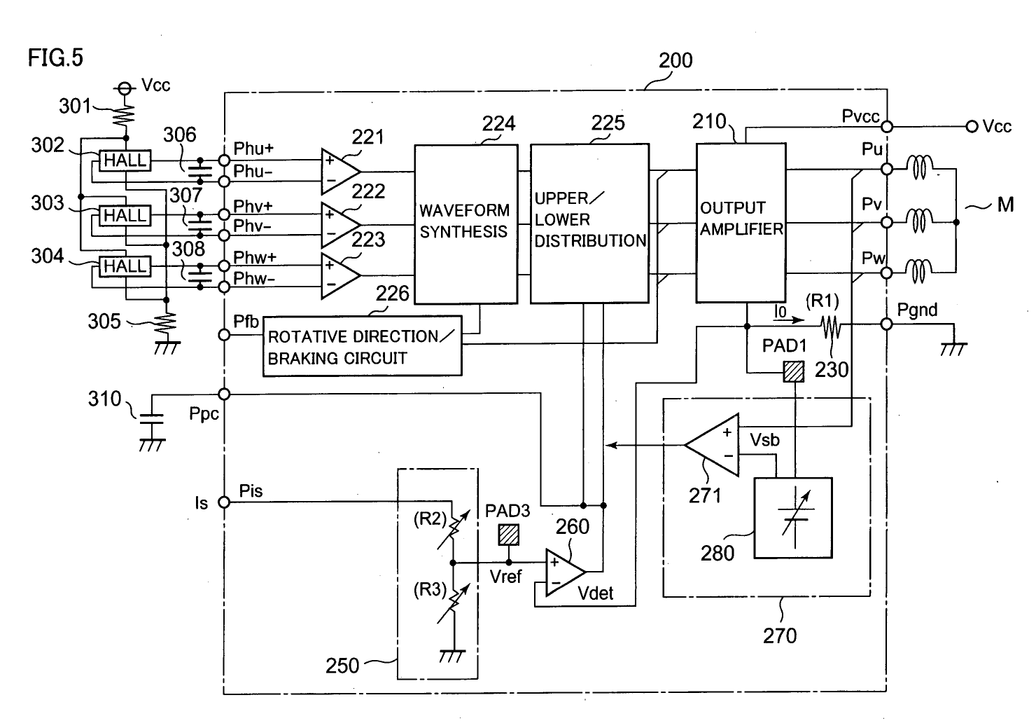

FIG. 5 shows a structure of a load-driving semiconductor device according to a fourth embodiment of the present invention, in which a three-phase motor is used as a load. In this example, a Hall element is used for detecting the position of a rotor. If a sensorless-type motor is used, load-driving semiconductor device 200 also has a similar structure.

In FIG. 5, Hall elements 302-304 are connected between supply voltage Vcc and the ground via resistors 301 and 305. Capacitors 306-308 and 310 are connected to load-driving semiconductor device 200. Detected signals of Hall elements 302-304 are input to Hall amplifiers 221-223 via terminals Phu+ to Phw−.

Load-driving semiconductor device 200 amplifies the detected signals of the Hall elements at Hall amplifiers 221-223, synthesizes the waveforms of the amplified signals and an output of a rotative direction/braking circuit 226 in a waveform synthesizer circuit 224, divides the obtained signals into upper and lower signals in an upper/lower distributor 225, amplifies the obtained signals in an output amplifier 210, and allows a current to flow through an appropriate phase coil of motor M via output terminals Pu-Pw. For example, in accordance with the position of a rotor, output current Io flows through a path from supply voltage Vcc through an upper output transistor of output amplifier 210, a U-phase coil, a V-phase coil, a lower output transistor of output amplifier 210, and a detecting resistor 230 to the ground.

Resistance value R1 of detecting resistor 230 is measured by using pad PAD1 and a ground terminal Pgnd. As such, if ground terminal Pgnd is used for measuring resistance value R1 of detecting resistor 230, a pad on a side of the ground (e.g. PAD2 in FIG. 1) may not be used.

In FIG. 5, detected voltage Vdet is used for controlling current feedback and saturation prevention. Therefore, a current feedback control circuit trims reference voltage Vref, while a saturation prevention control circuit trims a voltage Vsb set to prevent saturation. The current feedback control circuit and the saturation prevention control circuit correspond to the control circuit in the present invention.

A current command value Is is input to the current feedback control circuit via a terminal Pis. Current command value Is is adjusted in a trimming circuit 250 to be reference voltage Vref. Reference voltage Vref and detected voltage Vdet are compared in an error amplifier 260, which then generates a comparative signal. The comparative signal is applied to upper/lower distributor circuit 225 to control output current Io. Trimming circuit 250 may be similar to trimming circuit 50 as in FIGS. 1 and 2. A phase-compensating capacitor 310 is connected to an output end of error amplifier 260 via a terminal Ppc. Note that the current feedback control circuit is composed of error amplifier 260 and upper/lower distributor circuit 225.

The saturation prevention control circuit 270 compares an output voltage applied to motor M and voltage Vsb set to prevent saturation in a comparator 271, and when voltage Vsb set to prevent saturation exceeds the output voltage, reduces a comparative signal to be supplied to upper/lower distributor circuit 225. Accordingly, the output transistor of output amplifier 210 is operated in a linear region without saturation.

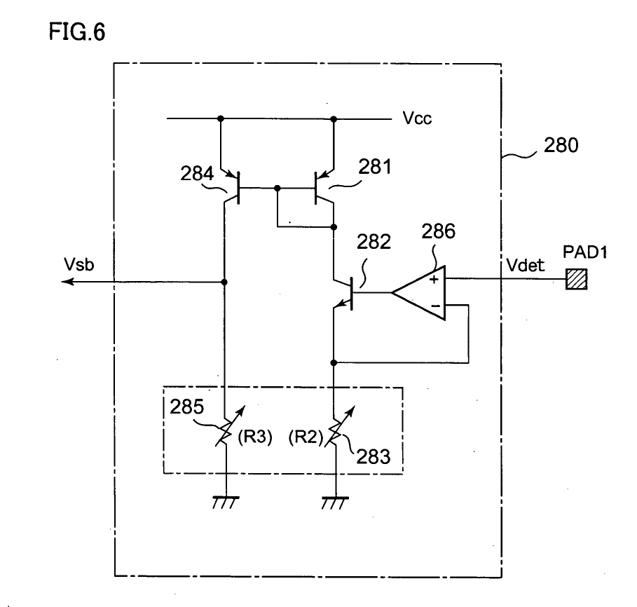

Voltage Vsb set to prevent saturation is generated in accordance with detected voltage Vdet in a circuit 280 as shown in FIG. 6 for generating a voltage set to prevent saturation.

In circuit 280 for generating a voltage set to prevent saturation, a PNP-type bipolar transistor (hereinafter referred to as a PNP transistor) 281 whose base and transistor are connected, an NPN-type bipolar transistor (hereinafter referred to as an NPN transistor) 282, and variably-adjustable resistor 283 are connected between supply voltage Vcc and the ground.

An output of a comparator 286, to which detected voltage Vdet and a voltage drop of variably-adjustable resistor 283 are input, is supplied to the base of NPN transistor 282.

In contrast, the base of PNP transistor 284 is connected to the base of PNP transistor 281, and PNP transistors 281 and 284 form a current mirror circuit. PNP transistor 284 and a variably-adjustable resistor 285 are connected between supply voltage Vcc and the ground, and voltage Vsb set to prevent saturation is output from the connecting point thereof.

Resistance value R2 of variably-adjustable resistor 283 and resistance value R3 of variably-adjustable resistor 285 are adjusted in a manner similar to the trimming of resistance value R2 and resistance value R3 in the trimming circuit in FIGS. 1 and 2. Accordingly, voltage Vsb set to prevent saturation can also be set accurately.

As such, the present invention can widely and suitably be applied to the electrical device that detects an output current to a load or a load current.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A load-driving semiconductor device for controlling drive of a load, comprising:
a detecting resistor formed of metal interconnection and for detecting an output current to said load; and
at least one resistance-measuring pad for measuring a resistance value of said detecting resistor.

2. The load-driving semiconductor device according to claim 1, further comprising:
a reference-voltage generator circuit for generating an adjustable reference voltage; and
a control circuit for controlling the drive of said load based on said reference voltage and a detected voltage according to a voltage drop of said detecting resistor.

3. The load-driving semiconductor device according to claim 2, wherein
said load-driving semiconductor device has a multi-layered metal interconnection layer, and
said detecting resistor is formed by using metal interconnection of an uppermost layer in said multi-layered metal interconnection layer.

4. The load-driving semiconductor device according to claim 3, further comprising a voltage-measuring pad for measuring said reference voltage.

5. The load-driving semiconductor device according to claim 2, wherein said reference-voltage generator circuit includes
a voltage generator circuit for generating a prescribed value of a generated voltage, and
a trimming circuit for trimming said generated voltage to generate said reference voltage.

6. The load-driving semiconductor device according to claim 5, wherein said trimming circuit has
a resistor-based voltage divider circuit having a plurality of resistors for dividing said generated voltage to output said reference voltage, and
a connecting portion connected in parallel to any of said plurality of resistors and disconnectably configured to adjust said reference voltage.

7. The load-driving semiconductor device according to claim 6, further comprising a voltage-measuring pad for measuring said reference voltage.

8. The load-driving semiconductor device according to claim 6, wherein said voltage generator circuit is configured to generate said generated voltage having a temperature coefficient of voltage substantially similar to a temperature coefficient of resistance of said detecting resistor.

9. The load-driving semiconductor device according to claim 8, further comprising a voltage-measuring pad for measuring said reference voltage.

10. The load-driving semiconductor device according to claim 5, wherein said trimming circuit has
a resistor-based voltage divider circuit having a plurality of resistors for dividing said generated voltage to output said reference voltage,
a switch connected in parallel to any of said plurality of resistors, and
a switch control circuit for controlling said switch to one of a conductive state and a non-conductive state to adjust said reference voltage.

11. The load-driving semiconductor device according to claim 10, further comprising a voltage-measuring pad for measuring said reference voltage.

12. The load-driving semiconductor device according to claim 10, wherein said voltage generator circuit is configured to generate said generated voltage having a temperature coefficient of voltage substantially similar to a temperature coefficient of resistance of said detecting resistor.

13. The load-driving semiconductor device according to claim 12, further comprising a voltage-measuring pad for measuring said reference voltage.

14. The load-driving semiconductor device according to claim 5, wherein said voltage generator circuit is configured to generate said generated voltage having a temperature coefficient of voltage substantially similar to a temperature coefficient of resistance of said detecting resistor.

15. The load-driving semiconductor device according to claim 14, further comprising a voltage-measuring pad for measuring said reference voltage.

16. The load-driving semiconductor device according to claim 5, further comprising a voltage-measuring pad for measuring said reference voltage.

17. The load-driving semiconductor device according to claim 2, further comprising a voltage-measuring pad for measuring said reference voltage.

18. The load-driving semiconductor device according to claim 1, wherein
said load-driving semiconductor device has a multi-layered metal interconnection layer, and
said detecting resistor is formed of metal interconnection of an uppermost layer in said multi-layered metal interconnection layer.

19. A load-driving semiconductor device for controlling drive of a load, comprising:
a detecting resistor formed of metal interconnection and for detecting an output current to said load;
at least one resistance-measuring pad for measuring a resistance value of said detecting resistor;
a reference-voltage generator circuit for generating an adjustable reference voltage; and
a control circuit for controlling the drive of said load based on a comparative signal obtained by comparing said reference voltage with a detected voltage according to a voltage drop of said detecting resistor, wherein
said control circuit controls timing of a control signal to an output transistor circuit in accordance with a prescribed control logic, and controls a level of said control signal based on said comparative signal.

20. The load-driving semiconductor device according to claim 19, wherein said control circuit further controls a level of said comparative signal in accordance with a comparative output obtained by comparing an output voltage applied to said load and a set voltage adjustable in accordance with said detected voltage.
